(19) United States
(12) Patent Application Publication
(10) Pub. No.: US 2022/0208577 A1
(43) Pub. Date: Jun. 30, 2022

(54) MANIPULATOR FINGER, MANIPULATOR, AND METHOD OF OPERATING THE SAME

(71) Applicant: Piotech Inc., Shenyang (CN)

(72) Inventors: Chun Liu, Shenyang (CN); Zongshuai Jiang, Shenyang (CN); Guangquan Lu, Shenyang (CN)

(21) Appl. No.: 17/547,666

(22) Filed: Dec. 10, 2021

(30) Foreign Application Priority Data
Dec. 31, 2020 (CN) 202011642969.0

(51) Int. Cl. H01L 21/67; H01L 21/687; B25J 19/02; G01K 7/02; G01K 1/14

(52) U.S. Cl. CPC H01L 21/67248; H01L 21/68707; G01K 1/14; G01K 7/02; B25J 19/02

(57) ABSTRACT

This application relates to a manipulator finger, a manipulator, and a method of operating the same. In an embodiment of this application, the manipulator finger includes: a finger; and one or more temperature measuring elements disposed in the finger and respectively connected to one or more temperature measuring contact points on a surface of the finger. The manipulator finger may be configured to monitor a temperature of a wafer in real time during delivery of the wafer.

### CROSS-REFERENCE TO RELATED APPLICATIONS

This application claims priority to Chinese Patent Application No. 202011642969.0 filed on Dec. 31, 2020, and all the benefits accruing therefrom under 35 U.S.C. § 119, the contents of which in its entirety are herein incorporated by reference.

### BACKGROUND OF THE INVENTION

### 1. Field of the Invention

This application generally relates to the field of semiconductor manufacturing devices, and more specifically to a manipulator finger, a manipulator, and a method of operating the same.

### 2. Description of the Related Art

In the semiconductor manufacturing process, usually a manipulator is used to perform the delivery of a wafer between chambers or between stations. A manipulator finger is mounted on a motor unit in a delivering chamber or in a front-end module, and rotates, extends, goes up and down, and the like with the motor unit. The wafer is placed on the manipulator finger and delivered between the chambers with the motion of the manipulator finger.

The temperature of a wafer is one of important indicators in the semiconductor manufacturing process. Monitoring and controlling the temperature of the wafer can improve the reliability of a product. However, a current semiconductor manufacturing device cannot monitor the temperature of a wafer during the delivery of the wafer.

### SUMMARY OF THE INVENTION

In order to overcome shortcomings in the prior art, this application provides a technical solution in which during delivery of a wafer, the temperature of the wafer can be monitored in real time by using a manipulator finger, providing support for optimizing parameters related to warming up or cooling down, the material, and the like of the wafer.

According to an aspect, this application provides a manipulator finger. The manipulator finger may include: a finger; and one or more temperature measuring elements disposed in the finger and respectively connected to one or more temperature measuring contact points on a surface of the finger.

According to an embodiment of this application, the finger may be rectangular, fan-shaped, or in a special shape similar to the shape of a finger.

According to an embodiment of this application, the material of the finger may be an insulating material.

According to an embodiment of this application, the insulating material may include ceramic.

According to an embodiment of this application, at least one contact structure configured to contact and support a wafer may be disposed on the surface of the finger.

According to an embodiment of this application, the contact structure may include at least one of a support contact point, a support wire, a support bevel, or a vacuum suction structure.

According to an embodiment of this application, at least one of the one or more temperature measuring contact points may be disposed at the contact structure.

According to an embodiment of this application, at least one of the one or more temperature measuring contact points may be disposed at an additional position different from the position of the contact structure.

According to an embodiment of this application, the initial height of the at least one temperature measuring contact point on which no wafer is placed may be greater than the height of the contact structure.

According to an embodiment of this application, a difference between the initial height and the height of the contact structure may be less than or equal to 1000 μm.

According to an embodiment of this application, the one or more temperature measuring elements may include thermocouple wires, the one or more temperature measuring contact points may include an electrically conductive coating applied over a surface of the one or more temperature measuring contact points, and measuring ends of the thermocouple wires may be electrically connected to the electrically conductive coating through the inside of the one or more temperature measuring contact points.

According to an embodiment of this application, the material of the electrically conductive coating may include gold, silver, platinum, tungsten, tantalum, molybdenum, titanium, nickel, aluminum, or any alloy thereof.

According to an embodiment of this application, the one or more temperature measuring contact points may further include a thermally conductive coating, where the thermally conductive coating may be applied over the electrically conductive coating.

According to an embodiment of this application, the material of the thermally conductive coating may include: AlN, SiC, sapphire, or diamond-like carbon.

According to an embodiment of this application, an output end of the one or more temperature measuring elements may be electrically connected to a pin arranged on the surface of the finger.

According to another aspect, this application further provides a manipulator. The manipulator may include: the manipulator finger according to any embodiment of this application; and a motor unit, where the manipulator finger is mounted on the motor unit.

According to an embodiment of this application, the motor unit may include an interface, where output signals generated by the one or more temperature measuring elements may be outputted through the interface.

According to yet another aspect, this application further provides a method for monitoring the temperature of a wafer by using the manipulator finger according to any embodiment of this application. The method may include: placing the wafer on the manipulator finger; and delivering the wafer to a target chamber by using the manipulator finger, where the one or more temperature measuring elements may monitor the temperature of the wafer in real time during delivery, generate corresponding output signals, and feed the output signals to a computer.

Details of one or more examples of this application are to be illustrated in the following accompanying drawings and description. Other features, objectives, and advantages become obvious according to the description, the accompanying drawings, and the claims.

### BRIEF DESCRIPTION OF THE DRAWINGS

Content disclosed in the specification mentions and includes the following figures:

FIG. 1 is a schematic structural view of a manipulator finger according to some embodiments of this application;

FIG. 2 is a schematic view of a fan-shaped finger according to some embodiments of this application;

FIG. 3 is a schematic view of a finger in a special shape similar to the shape of a finger according to some embodiments of this application;

FIG. 4 is a schematic view of a connection structure of a temperature measuring contact point disposed at a support contact point and a temperature measuring element according to some embodiments of this application;

FIG. 5 is a schematic view of another connection structure of a temperature measuring contact point disposed at a support contact point and a temperature measuring element according to some embodiments of this application;

FIG. 6 is a schematic view of a connection structure of a temperature measuring contact point disposed at an additional position and a temperature measuring element according to some embodiments of this application;

FIG. 7 is a schematic view of a connection structure of a pin and a temperature measuring element according to some embodiments of this application;

FIG. 8 is a schematic view of a manipulator finger on which a wafer is placed according to some embodiments of this application;

FIG. 9 is a schematic structural view of another manipulator finger according to some embodiments of this application;

FIG. 10 shows a side view of the manipulator finger in FIG. 9 and a local cross-sectional view of a temperature measuring contact point and a pin;

FIG. 11 is a schematic structural view of yet another manipulator finger according to some embodiments of this application;

FIG. 12 shows a side view of the manipulator finger in FIG. 11 and a local cross-sectional view of a temperature measuring contact point; and

FIG. 13 is a schematic structural view of a semiconductor processing system to which a manipulator finger is applied according to some embodiments of this application.

According to the convention, features illustrated in the figures may not be drawn in proportion. Therefore, the sizes of the various features may be increased or reduced arbitrarily for the purpose of clearness. The shape of each component illustrated in the figures is merely exemplary, and is not to limit the actual shape of the component. In addition, for clearness, implementations described in the figures may be simplified. Therefore, all components of a given device or apparatus may not be described in the figures. Finally, similar reference numerals may be used to represent similar features throughout the specification and the figures.

### PREFERRED EMBODIMENT OF THE PRESENT INVENTION

To better understand the spirit of this application, this application is further described below with reference to some embodiments of this application.

Phases used in the specification such as “in an embodiment” or “according to an embodiment” do not mean necessarily referring to the same specific embodiment. Besides, “in other (some/certain) embodiments” or “according to other (some/certain) embodiments” used in the specification does not mean necessarily referring to different specific embodiments. The objective is, for example, that the claimed subject matter includes a combination of all or part of specific exemplary embodiments. The meanings of “up” and “down” in the specification are not limited to the relationship directly shown in the figures, but should include specific description of correspondences, such as “left” and “right” or opposition of “up” and “down”. “Connection” in the specification should be understood as covering “direct connection” and “connection through one or more intermediate components”. Names of various components used in the specification are merely provided for purposes of illustration, and are not intended to be limitations. Different manufacturers can refer to components with the same function by using different names.

Embodiments of this application will be discussed below in detail. Although specific implementations are discussed, it should be understood that the implementations are merely provided for purposes of illustration. A person skilled in the art should realize that other components and configurations may be used without departing from the spirit and the protection scope of this application. The implementations in this application do not necessarily include all components or steps in the embodiments described in the specification. An order of performing steps may be alternatively adjusted according to actual application.

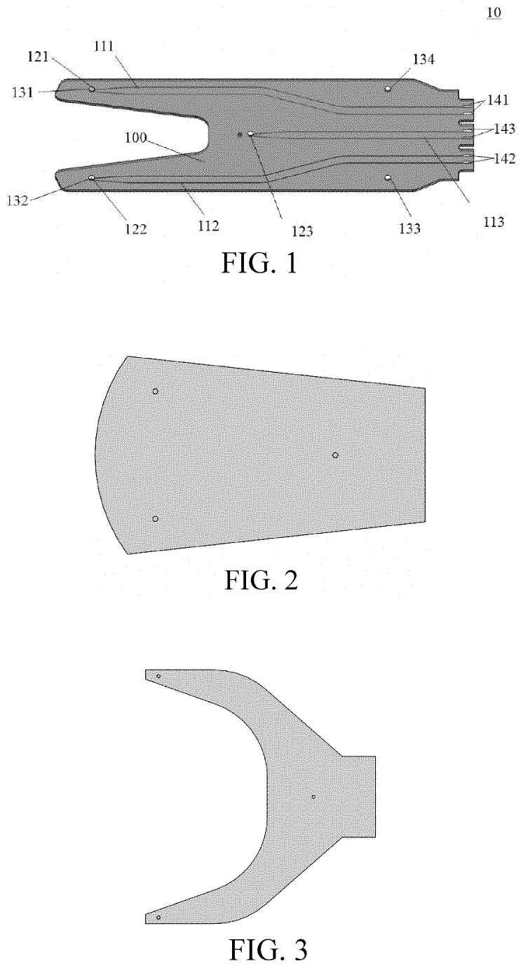

FIG. 1 is a schematic structural view of a manipulator finger 10 according to some embodiments of this application. The manipulator finger 10 includes a finger 100 and temperature measuring elements 111, 112, and 113. For convenience, in FIG. 1, the temperature measuring elements 111, 112, and 113 are shown on a surface of the finger 100. Actually, the temperature measuring elements 111, 112, and 113 are disposed in the finger 100 and are respectively connected to temperature measuring contact points 121, 122, and 123 on the surface of the finger 100. Although FIG. 1 shows a specific quantity of temperature measuring elements and temperature measuring contact points, a person skilled in the art should understand that the manipulator finger 10 may include fewer or more temperature measuring elements and temperature measuring contact points. For example, the manipulator finger 10 may include merely one temperature measuring element and one temperature measuring contact point.

The finger 100 is generally rectangular, but is not limited thereto. The finger 100 may be in any appropriate shape. FIG. 2 shows a fan-shaped finger according to some embodiments of this application. FIG. 3 shows a finger in a special shape similar to the shape of a finger according to some embodiments of this application.

In some embodiments, the material of the finger 100 may be an insulating material. In some embodiments, the insulating material includes but is not limited to ceramic.

In an example of FIG. 1, the temperature measuring elements 111, 112, and 113 are thermocouple wires. In another embodiment of this application, another temperature measuring element with a similar function may be used. The temperature measuring elements 111, 112, and 113 each have one end (also referred to as a measuring end) electrically connected to the temperature measuring contact points 121, 122, and 123, respectively. The temperature measuring elements 111, 112, and 113 each have the other end (also referred to as an output end) electrically connected to pins 141, 142, and 143 arranged on the surface of the finger 100, respectively. In some embodiments, the temperature measuring elements 111, 112, and 113 may be connected to an acquisition module respectively through the pins 141, 142, and 143, convert temperature signals acquired by the temperature measuring elements 111, 112, and 113 into electrical signals and output the electrical signals to the acquisition module.

Support contact points 131, 132, 133, and 134 configured to contact and support a wafer are disposed on the surface of the finger 100. The temperature measuring contact points 121 and 122 are respectively disposed at the support contact points 131 and 132. In other words, the support contact points 131 and 132 are both support contact points and temperature measuring contact points. The temperature measuring contact point 123 is disposed at an additional position different from positions of the support contact points 131, 132, 133, and 134. Although FIG. 1 shows a specific quantity of support contact points, a person skilled in the art should understand that fewer or more support contact points may be disposed on the surface of the finger 100. One or more temperature measuring contact points may be disposed at the support contact points or additional positions different from the positions of the support contact points according to requirements. The additional position is within a projection plane of the wafer on the finger, that is, when the wafer is placed on the finger, the wafer covers the additional position.

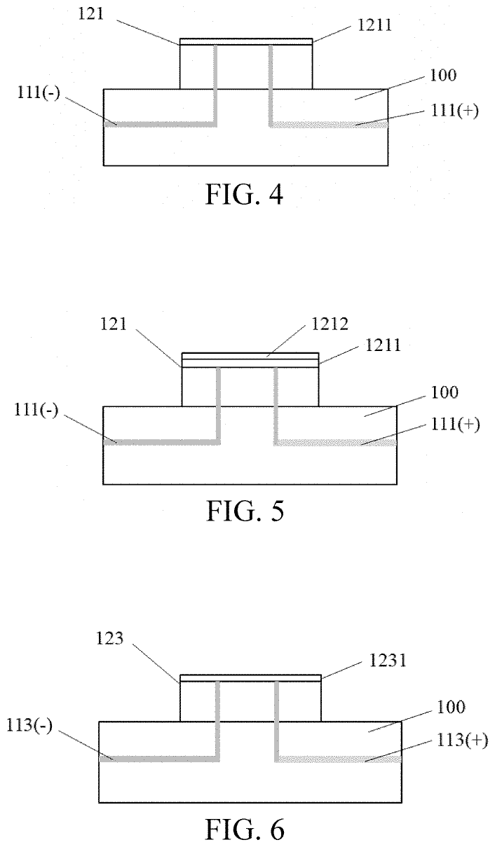

FIG. 4 shows a connection structure of a temperature measuring contact point (for example, the temperature measuring contact point 121 in FIG. 1) which is disposed at a support contact point on a surface of a finger (for example, the finger 100 in FIG. 1) and a temperature measuring element (for example, the temperature measuring element 111 in FIG. 1) according to some embodiments of this application. As shown in FIG. 4, the temperature measuring element 111 includes thermocouple wires 111(+) and 111(−). The thermocouple wires 111(+) and 111(−) are embedded inside the finger 100 and the temperature measuring contact point 121. The temperature measuring contact point 121 includes an electrically conductive coating 1211 applied over a surface of the temperature measuring contact point 121. Measuring ends of the thermocouple wires 111(+) and 111(−) are individually connected to the electrically conductive coating 1211 through the inside of the temperature measuring contact point 121, to implement electrical connection between the temperature measuring contact point 121 and the temperature measuring element 111. The electrically conductive coating 1211 may be connected to the measuring ends of the thermocouple wires 111(+) and 111(−) in a manner such as welding, coating, or spraying.

To ensure good electrical conductivity of the thermocouple wires 111(+) and 111(−) and extend the service life of the thermocouple wires, the electrically conductive coating 1211 may be made of a metal or an alloy material with good electrical conductivity and good thermal conductivity. In some embodiments, the material of the electrically conductive coating 1211 may include gold, silver, platinum, tungsten, tantalum, molybdenum, titanium, nickel, aluminum, or any alloy thereof.

The material of the electrically conductive coating 1211 may be elastic. When the wafer is placed on the finger 100 and is supported by the support contact points on the surface of the finger, the electrically conductive coating 1211 on the support contact point 131 (that is, the temperature measuring contact point 121) may deform to some extent under the gravity of the wafer, so as to ensure that when more than two temperature measuring elements are arranged, even though the wafer is warped, the wafer can be in good contact with more than two temperature measuring contact points.

The main body (that is, the part below the electrically conductive coating 1211 of the temperature measuring contact point 121) of the support contact point may be made of an insulating material. In some embodiments, the insulating material includes but is not limited to ceramic. In some embodiments, the material of the main body may be the same as the material of the finger 100. For example, the main body and the finger 100 may be integrally formed. In some embodiments, the material of the main body may be different from the material of the finger 100.

In some embodiments, the temperature measuring contact point 121 may further include a thermally conductive coating which has excellent thermal conductivity and is not easy to cause contamination of particles or impurities when in contact with the wafer. FIG. 5 shows another connection structure of a temperature measuring contact point (for example, the temperature measuring contact point 121 in FIG. 1) which is disposed at a support contact point on a surface of a finger (for example, the finger 100 in FIG. 1) and a temperature measuring element (for example, the temperature measuring element 111 in FIG. 1) according to some embodiments of this application. As shown in FIG. 5, the temperature measuring contact point 121 includes an electrically conductive coating 1211 applied over a surface of the temperature measuring contact point 121 and a thermally conductive coating 1212 applied over the electrically conductive coating 1211. In some embodiments, the material of the thermally conductive coating 1212 may include AlN, SiC, sapphire, or diamond-like carbon. Thermocouple wires 111(+) and 111(−) are embedded inside the finger 100 and the temperature measuring contact point 121. Measuring ends of the thermocouple wires 111(+) and 111(−) are individually connected to the electrically conductive coating 1211 through the inside of the temperature measuring contact point 121, to implement electrical connection between the temperature measuring contact point 121 and the temperature measuring element 111. The electrically conductive coating 1211 may be connected to the measuring ends of the thermocouple wires 111(+) and 111(−) in a manner such as welding, coating, or spraying.

FIG. 6 is a schematic view of a connection structure of a temperature measuring contact point (for example, the temperature measuring contact point 123 in FIG. 1) which is disposed at an additional position on a surface of a finger (for example, the finger 100 in FIG. 1) and a temperature measuring element (for example, the temperature measuring element 113 in FIG. 1) according to some embodiments of this application. As shown in FIG. 6, the temperature measuring element 113 includes thermocouple wires 113(+) and 113(−). The thermocouple wires 113(+) and 113(−) are embedded inside the finger 100 and the temperature measuring contact point 123. The temperature measuring contact point 123 includes an electrically conductive coating 1231 applied over a surface of the temperature measuring contact point 123. Measuring ends of the thermocouple wires 113(+) and 113(−) are individually connected to the electrically conductive coating 1231 through the inside of the temperature measuring contact point 123, to implement electrical connection between the temperature measuring contact point 123 and the temperature measuring element 113. The electrically conductive coating 1231 may be connected to the measuring ends of the thermocouple wires 113(+) and 113(−) in a manner such as welding, coating, or spraying.

To ensure good electrical conductivity of the thermocouple wires 113(+) and 113(−) and extend the service life of the thermocouple wires, the electrically conductive coating 1231 may be made of a metal or an alloy material with good electrical conductivity and good thermal conductivity. In some embodiments, the material of the electrically conductive coating 1231 may include gold, silver, platinum, tungsten, tantalum, molybdenum, titanium, nickel, aluminum, or any alloy thereof.

In some embodiments, the temperature measuring contact point 123 may further include a thermally conductive coating (not shown in the figure) applied over the electrically conductive coating 1231. The thermally conductive coating may be made of a material which has excellent thermal conductivity and is not easy to cause contamination of particles or impurities when in contact with the wafer. The material of the thermally conductive coating may include AlN, SiC, sapphire, or diamond-like carbon.

The main body (that is, the part below the electrically conductive coating 1231) of the temperature measuring contact point 123 may be made of an insulating material with certain elasticity. In some embodiments, the initial height of the temperature measuring contact point 123 on which no wafer is placed may be greater than the height of the support contact point (for example, the support contact point 133 or 134). In some embodiments, a difference between the initial height of the temperature measuring contact point 123 and the height of the support contact point may be less than or equal to 1000 μm. In some embodiments, a difference between the initial height of the temperature measuring contact point 123 and the height of the support contact point is less than or equal to 100 μm, 200 μm, 500 μm, or 800 μm. When being placed on the finger 100, the wafer may first come into contact with the temperature measuring contact point 123. The main body of the temperature measuring contact point 123 may deform to some extent under the gravity of the wafer, so that the wafer can further come into contact with the support contact point and be supported by the support contact point, and be in good contact with the temperature measuring contact point 123 at the same time. The electrically conductive coating 1213 of the temperature measuring contact point 123 may also deform to some extent under the gravity of the wafer.

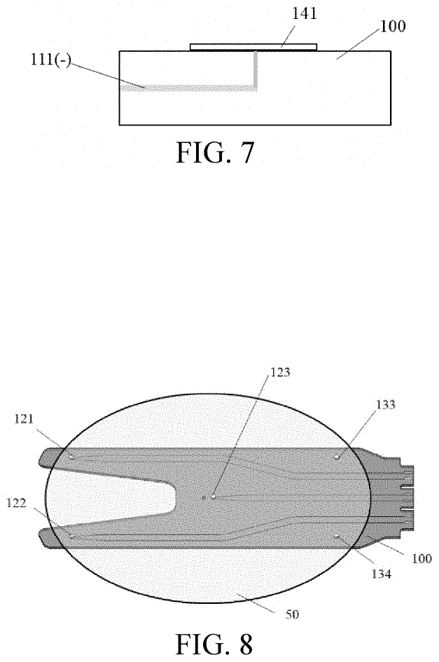

FIG. 7 shows a connection structure of a pin and a temperature measuring element according to some embodiments of this application. For example, FIG. 7 may exemplarily show a part where the pin 141 on the surface of the finger 100 is connected to a thermocouple wire 111(−) in FIG. 1. The pin 141 includes an electrically conductive coating applied over the surface of the finger 100. The electrically conductive coating may be made of a material with good thermal conductivity and corrosion resistance. In some embodiments, the material of the electrically conductive coating of the pin 141 may include gold, silver, platinum, tungsten, tantalum, molybdenum, titanium, nickel, aluminum, or any alloy thereof. In the example of FIG. 7, the thermocouple wire 111(−) embedded inside the finger 100 is connected to a lower surface of the pin 141, to implement electrical connection between the pin 141 and an output end of the temperature measuring element 111. The pin 141 may be connected to the output end of the thermocouple wire 111(−) in a manner such as welding, coating, or spraying. Another output end of the temperature measuring element 111 may be electrically connected to another pin in a similar way.

FIG. 8 is a schematic view of a manipulator finger (for example, the manipulator finger including the finger 100 in FIG. 1) on which a wafer is placed according to some embodiments of this application. As shown in FIG. 8, a wafer 50 is placed on the manipulator finger, is supported by the support contact points 131 (that is, the temperature measuring contact point 121), 132 (that is, the temperature measuring contact point 122), 133, and 134 which are on the surface of the finger 100, and is in contact with the temperature measuring contact points 121, 122, and 123 at the same time. The temperature measuring elements connected to the temperature measuring contact points 121, 122, and 123 can measure the temperature of the wafer 50. Therefore, when the wafer 50 is placed on the manipulator finger, the temperature of the wafer 50 can be measured in real time when the manipulator finger stays still or moves.

In the examples shown in FIG. 1 to FIG. 8, the contact structure disposed on the surface of the finger and configured to contact and support the wafer is a support contact point. Alternatively or additionally, in other embodiments of this application, the contact structure disposed on the surface of the finger may include at least one of a support wire, a support bevel, or a vacuum suction structure.

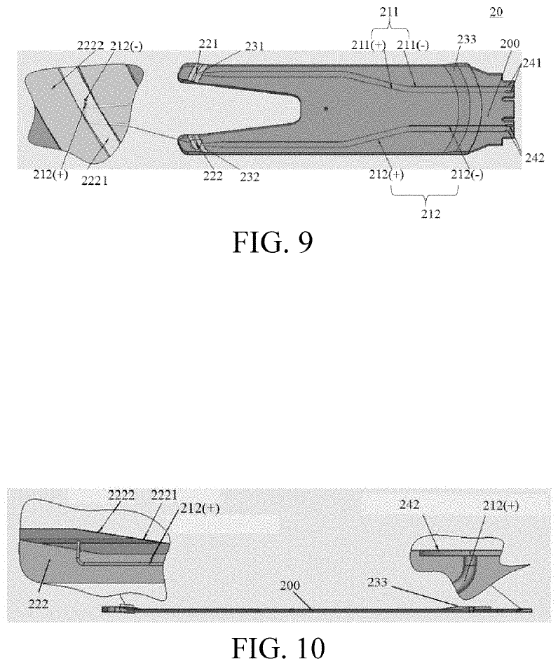

FIG. 9 is a schematic structural view of another manipulator finger according to some embodiments of this application. In the example, a contact structure disposed on the manipulator finger is a support bevel. When a wafer is placed on the manipulator finger, the edge of the wafer is in contact with and supported by the support bevel. As shown by the right part in FIG. 9, the manipulator finger 20 includes a finger 200 and temperature measuring elements 211 and 212. The temperature measuring element 211 is disposed inside the finger 200 and includes thermocouple wires 211(+) and 211(−). Measuring ends of the thermocouple wires 211(+) and 211(−) are connected to a temperature measuring contact point 221 disposed on a surface of the finger 200. Output ends of the thermocouple wires 211(+) and 211(−) are connected to a pin 241 disposed on the surface of the finger 200. The temperature measuring element 212 is disposed inside the finger 200 and includes thermocouple wires 212(+) and 212(−). Measuring ends of the thermocouple wires 212(+) and 212(−) are connected to a temperature measuring contact point 222 disposed on the surface of the finger 200. Output ends of the thermocouple wires 212(+) and 212(−) are connected to a pin 242 disposed on the surface of the finger 200. In the example shown in FIG. 9, the temperature measuring contact point 221 and the temperature measuring contact point 222 are respectively disposed at support bevels 231 and 232. No temperature measuring contact point is disposed at a support bevel 233. In other embodiments, more or fewer temperature measuring contact points may be disposed, and the temperature measuring contact point(s) may be disposed at other position(s).

The left part in FIG. 9 is a local enlarged view of the temperature measuring contact point 222. The temperature measuring contact point 222 includes an electrically conductive coating 2221 applied over a surface of the temperature measuring contact point 222, and a thermally conductive coating 2222. The thermally conductive coating 2222 may be applied over a surface of the electrically conductive coating 2221. The electrically conductive coating 2221 may be made of a metal or an alloy material with good electrical conductivity and good thermal conductivity. In some embodiments, the material of the electrically conductive coating 2221 may include gold, silver, platinum, tungsten, tantalum, molybdenum, titanium, nickel, aluminum, or any alloy thereof. The thermally conductive coating 2222 may be made of a material which has excellent thermal conductivity and is not easy to cause contamination of particles or impurities when in contact with the wafer. The material of the thermally conductive coating may include AlN, SiC, sapphire, or diamond-like carbon. In some embodiments, the temperature measuring contact point 222 may not include the thermally conductive coating 2222 applied over the surface of the electrically conductive coating 2221.

FIG. 10 shows a side view of the manipulator finger 20 in FIG. 9 and a local cross-sectional view of the temperature measuring contact point 222 and the pin 242. As shown in FIG. 10, the contact structure disposed on the surface of the finger 200 and configured to contact and support the wafer is a support bevel (for example, the support bevel 232 or 233). The temperature measuring contact point 222 is located at the support bevel 232. The thermocouple wire 212(+) is embedded inside the finger 200 and the temperature measuring contact point 222. The measuring end of the thermocouple wire 212(+) is connected to the electrically conductive coating 2221 of the temperature measuring contact point 222 through the inside of the temperature measuring contact point 222. The pin 242 includes an electrically conductive coating applied over the surface of the finger 200. The electrically conductive coating may be made of a material with good electrical conductivity and thermal conductivity and corrosion resistance. In some embodiments, the material of the electrically conductive coating of the pin 242 may include gold, silver, platinum, tungsten, tantalum, molybdenum, titanium, nickel, aluminum, or any alloy thereof. The output end of the thermocouple wire 212(+) of the temperature measuring element 212 is connected to a lower surface of the electrically conductive coating of the pin 242 through the inside of the finger 200.

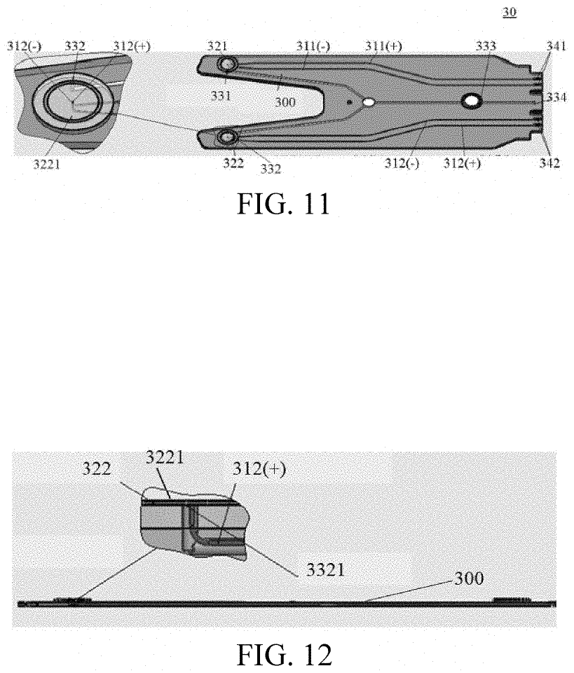

FIG. 11 is a schematic structural view of yet another manipulator finger according to some embodiments of this application. In the example, a contact structure disposed on the manipulator finger is a vacuum suction structure (for example, a vacuum suction cup). When a wafer is placed on the manipulator finger, the vacuum suction structure can suck the wafer. As shown by the right part in FIG. 11, the manipulator finger 30 includes a finger 300 and temperature measuring elements 311 and 312. The temperature measuring element 311 is disposed inside the finger 300 and includes thermocouple wires 311(+) and 311(−). Measuring ends of the thermocouple wires 311(+) and 311(−) are connected to a temperature measuring contact point 321 disposed on the surface of the finger 300. Output ends of the thermocouple wires 311(+) and 311(−) are connected to a pin 341 disposed on the surface of the finger 300. The temperature measuring element 312 is disposed inside the finger 300 and includes thermocouple wires 312(+) and 312(−). Measuring ends of the thermocouple wires 312(+) and 312(−) are connected to a temperature measuring contact point 322 disposed on the surface of the finger 300. Output ends of the thermocouple wires 312(+) and 312(−) are connected to a pin 342 disposed on the surface of the finger 300.

As shown in FIG. 11, vacuum suction structures 331, 332, and 333 are disposed on the surface of the finger 300. The finger 300 sucks, through the vacuum suction structures 331, 332, and 333, the wafer to the surface of the finger 300 to support the wafer. The vacuum suction structures 331, 332, and 333 are connected with one another through an air passage inside the finger 300. The air passage is connected to an air output end 334 for air pumping and air exhaust. The temperature measuring elements 311 and 312 are respectively disposed at the vacuum suction structures 331 and 332.

The left part in FIG. 11 is a local enlarged view of the temperature measuring contact point 322. The temperature measuring contact point 322 includes an electrically conductive coating 3221 applied over a surface of the temperature measuring contact point 322. The electrically conductive coating 3221 may be made of a metal or an alloy material with good electrical conductivity and good thermal conductivity. In some embodiments, the material of the electrically conductive coating 3221 may include gold, silver, platinum, tungsten, tantalum, molybdenum, titanium, nickel, aluminum, or any alloy thereof. FIG. 12 shows a side view of the manipulator finger 30 in FIG. 11 and a local cross-sectional view of the temperature measuring contact point 322. As shown in FIG. 11 and FIG. 12, the measuring ends of the thermocouple wires 312(+) and 312(−) are connected, through the inside of the temperature measuring contact point 322, to the electrically conductive coating 3221 applied over the surface of the temperature measuring contact point 322. The temperature measuring contact point 322 is disposed at the vacuum suction structure 332, so that the wafer is sucked to the surface of the finger 300 under the action of the vacuum suction structure 332 and is in contact with the temperature measuring contact point 322. In some embodiments, the temperature measuring contact point 322 may further include a thermally conductive coating applied over the electrically conductive coating 3221. The thermally conductive coating may be made of a material which has excellent thermal conductivity and is not easy to cause contamination of particles or impurities when in contact with the wafer. The material of the thermally conductive coating may include AlN, SiC, sapphire, or diamond-like carbon. FIG. 12 further shows an air passage 3321 connected to the vacuum suction structure 332.

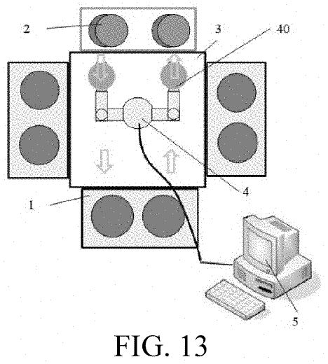

FIG. 13 is a schematic structural view of a semiconductor processing system to which a manipulator finger is applied according to some embodiments of this application. The semiconductor processing system includes a loading chamber 2, a delivering chamber 3, and three process chambers 1. Although FIG. 13 shows a specific quantity of process chambers and loading chambers, a person skilled in the art should understand that the semiconductor processing system may include fewer or more process chambers and loading chambers.

As shown in FIG. 13, the manipulator finger 40 is mounted on a motor unit 4 in the delivering chamber 3. The manipulator finger 40 may move, for example, rotate, extend, and go up and down with the motor unit 4, so that a wafer loaded on the manipulator finger 40 may also move with driving of the manipulator finger 40. For example, as shown by arrows in FIG. 13, the manipulator finger 40 may take a wafer out from the loading chamber 2 and then deliver the wafer to any process chamber 1 for processing; or the manipulator finger 40 may take a processed wafer out from any process chamber 1 and then deliver the processed wafer to the loading chamber 2 or another process chamber 1. When a wafer is placed on the manipulator finger 40 for delivery, a temperature measuring element on the manipulator finger 40 can monitor the temperature of the wafer in real time and generate a corresponding output signal. The motor unit 4 includes an interface connected to an external computer 5. The output signal generated by the temperature measuring element on the manipulator finger 40 may be fed to the computer 5 through the interface of the motor unit 4.

In some embodiments, the manipulator finger 40 may be mounted on a motor unit in a front-end module.

In some embodiments, the interface of the motor unit 4 may include a wired interface or a wireless interface, so that the output signal generated by the temperature measuring element can be outputted to the computer 5 in a wired or wireless manner. The computer 5 can process the signal received from the motor unit 4 and display related information, such as a temperature-time curve generated in real time. In some embodiments, the interface of the motor unit 4 may include a Bluetooth interface.

In some embodiments, a method for monitoring the temperature of a wafer by using the manipulator finger according to this application may include: placing the wafer on the manipulator finger; and delivering the wafer to a target chamber by using the manipulator finger, where the one or more temperature measuring elements in the manipulator finger monitor the temperature of the wafer in real time during delivery, generate corresponding output signals, and feed the output signals to a computer.

Compared with the existing manipulator finger, the manipulator finger in this application can resolve a problem that the temperature of a wafer cannot be measured during delivery. The manipulator finger in this application may be configured to monitor the temperature change of a wafer from a process chamber or a loading chamber in a period from the time of being placed on the manipulator finger to the time of leaving the manipulator finger. Therefore, the manipulator finger in this application can monitor the temperature change of a wafer in real time during delivery. By monitoring the temperature change of the wafer, the time for which the wafer is controlled to be warmed up or cooled down can be calculated, thereby providing support for improving the process reliability and the production capacity. Moreover, temperature resistance of a material in contact with the wafer can be evaluated.

The description of the specification is provided to enable a person skilled in the art to implement or use this application. Various modifications to this application will be readily apparent to those skilled in the art, and the generic principles defined herein may be applied to other alterations without departing from the spirit or scope of this application. Therefore, this application is not limited to the examples and designs described in this specification, but is given the widest scope consistent with the principles and novel features disclosed herein.

1. A manipulator finger, comprising:
a finger; and
one or more temperature measuring elements disposed in the finger and respectively connected to one or more temperature measuring contact points on a surface of the finger.

2. The manipulator finger according to claim 1, wherein the finger is rectangular, fan-shaped, or in a special shape similar to a shape of a finger.

3. The manipulator finger according to claim 1, wherein a material of the finger is an insulating material.

4. The manipulator finger according to claim 3, wherein the insulating material comprises ceramic.

5. The manipulator finger according to claim 1, wherein at least one contact structure configured to contact and support a wafer is disposed on the surface of the finger.

6. The manipulator finger according to claim 5, wherein the contact structure comprises at least one of a support contact point, a support wire, a support bevel, or a vacuum suction structure.

7. The manipulator finger according to claim 5, wherein at least one of the one or more temperature measuring contact points is disposed at the contact structure.

8. The manipulator finger according to claim 5, wherein at least one of the one or more temperature measuring contact points is disposed at an additional position different from a position of the contact structure.

9. The manipulator finger according to claim 8, wherein an initial height of the at least one temperature measuring contact point on which no wafer is placed is greater than a height of the contact structure.

10. The manipulator finger according to claim 9, wherein a difference between the initial height and the height of the contact structure is less than or equal to 1000 μm.

11. The manipulator finger according to claim 1, wherein the one or more temperature measuring elements comprise thermocouple wires, the one or more temperature measuring contact points comprise an electrically conductive coating applied over a surface of the one or more temperature measuring contact points, and measuring ends of the thermocouple wires are electrically connected to the electrically conductive coating through the inside of the one or more temperature measuring contact points.

12. The manipulator finger according to claim 11, wherein a material of the electrically conductive coating comprises gold, silver, platinum, tungsten, tantalum, molybdenum, titanium, nickel, aluminum, or any alloy thereof.

13. The manipulator finger according to claim 11, wherein the one or more temperature measuring contact points further comprise a thermally conductive coating applied over the electrically conductive coating.

14. The manipulator finger according to claim 13, wherein a material of the thermally conductive coating comprises: AlN, SiC, sapphire, or diamond-like carbon.

15. The manipulator finger according to claim 1, wherein an output end of the one or more temperature measuring elements is electrically connected to a pin arranged on the surface of the finger.

16. A manipulator, comprising:
the manipulator finger according to claim 1; and
a motor unit, wherein the manipulator finger is mounted on the motor unit.

17. The manipulator according to claim 16, wherein the motor unit comprises an interface through which output signals generated by the one or more temperature measuring elements are outputted.

18. A method for monitoring a temperature of a wafer by using the manipulator finger according to claim 1, the method comprising:
placing the wafer on the manipulator finger; and
delivering the wafer to a target chamber by using the manipulator finger, wherein the one or more temperature measuring elements monitor the temperature of the wafer in real time during delivery, generate corresponding output signals, and feed the output signals to a computer.
